(19) United States
(12) Patent Application Publication
(10) Pub. No.: US 2024/0006413 A1
(43) Pub. Date: Jan. 4, 2024

(54) INDEPENDENT GATE STACK FOR SINGLE NANOWIRE STANDARD CELL TRANSISTORS

(71) Applicant: Intel Corporation, Santa Clara, CA (US)

(72) Inventors: Abhishek Sharma, Portland, OR (US); Tahir Ghani, Portland, OR (US); Wilfred Gomes, Portland, OR (US); Anand Murthy, Portland, OR (US)

(73) Assignee: Intel Corporation, Santa Clara, CA (US)

(21) Appl. No.: 17/856,869

(22) Filed: Jul. 1, 2022

(51) Int. Cl. H01L 27/092; H01L 29/423; H01L 29/786; H01L 29/06; H01L 23/367; H01L 21/8238

(52) U.S. Cl. CPC H01L 27/092; H01L 29/42392; H01L 29/78696; H01L 29/0673; H01L 23/367; H01L 21/823814; H01L 21/823842

(57) ABSTRACT

Integrated circuit dies, systems, and techniques are described herein related to three-dimensional dynamic random access memory. A memory device includes vertically aligned semiconductor structures coupled to independent gate structures, corresponding vertically aligned capacitors each coupled to a corresponding one of the semiconductor structures, and a bit line contact extending vertically across a depth of the semiconductor structures and coupled to each of the semiconductor structures.

### BACKGROUND

There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. Notably, there is a desire to further condense transistor devices for increased efficiency. Such higher density transistor devices may be used in any computational context.

It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional view of an example multi-transistor structure device;

FIGS. 2A, 2B, 2C, 3A, 3B, 3C, and 4-17 illustrate example multi-transistor structures as selected fabrication operations are performed;

FIG. 18 illustrates a cross-sectional view of an example integrated circuit die including multi-transistor structures;

FIG. 19 illustrates a cross-sectional view of a multi-transistor structure IC system for implementation at very low temperature;

FIG. 20 illustrates a cross-sectional view of a low temperature multi-transistor structure IC system using die level cooling;

FIG. 21 illustrates a cross-sectional view of a low temperature multi-transistor structure IC system using package level cooling;

FIG. 22 illustrates a cross-sectional view of a low temperature multi-transistor structure IC system using die level and package level cooling;

FIG. 23 illustrates a view of an example two-phase immersion cooling system for low temperature operation of an integrated circuit die having multi-transistor structures; and

FIG. 24 illustrates diagram of an example data server machine employing a low temperature multi-transistor structure based integrated circuit system; and

FIG. 25 is a block diagram of an example computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the term predominantly indicates the predominant constituent (i.e., greater than 50% is the constituent of greatest proportion in the layer or material). The term substantially pure indicates the constituent is not less than 99% of the material. The term pure indicates the constituent is not less than 99.5% of the material and the term completely pure indicates the constituent is not less than 99.9% of the material. As used herein, the terms “monolithic”, “monolithically integrated”, and similar terms indicate the components of the monolithic overall structure form an indivisible whole not reasonably capable of being separated.

Integrated circuit dies, systems, circuits, and techniques are described herein related to independent gate stacks for single semiconductor structure transistors for improved device density.

Embodiments discussed herein provide advantageous independent gate stacks inclusive of a number of independent gate structures, each to control one of a number of vertically aligned semiconductor structures. Such transistor structures provide a single semiconductor structure standard cell transistor. As used herein, the term standard cell indicates a three-terminal transistor (gate, source, drain). The term single semiconductor structure indicates each gate is coupled to a single monolithic semiconductor structure such that each gate structure couples to a channel region of only one semiconductor structure of a group of vertically aligned semiconductor structures. Such standard cell transistors may be deployed in any computational device or context.

In some embodiments, the devices or systems are deployed at very low temperatures, such as at or below 0° C. In some embodiments, very low temperature deployment allows for single semiconductor structure transistors with very small semiconductor structure cross-sectional dimensions such as thicknesses in the range of 0.5 to 20 nm with thicknesses of not more than 2 nm being used in some contexts. In some embodiments, the transistors are implemented in an integrated circuit (IC) die including or coupled to cooling structure operable to remove heat from the IC die to achieve an operating temperature at the very low temperature. As used herein, the term cooling structure or active cooling structure indicates a device that uses power to provide cooling (e.g., via flow of a coolant, immersion in a coolant, etc.). Notably, the cooling structure or active cooling structure need not be in operation to be labeled as such. The active cooling structure may be part of the IC die and/or provided separately from the IC die. In some contexts, an active cooling structure is not needed as the IC die is deployed in a very low temperature environment such as in any of a subpolar oceanic climate, a subarctic climate, an arctic climate, a tundra climate, an ice cap climate, or any other environment of sustained cold temperatures. In some embodiments, the discussed transistors are implemented in room temperature (or room temperature devices) without use of such cooling structures (although typical cooling techniques such as heat sinks may be used).

In some embodiments, a device includes a multi-transistor structure including a number of vertically aligned semiconductor structures. As used herein, the term semiconductor structure indicates a structure of semiconductor material and is inclusive of nanowires or nanoribbons, nanosheets, or fins. In some contexts, embodiments are discussed with respect to nanowires for the sake of clarity of presentation; however, any semiconductor structures may be deployed. Each semiconductor structure includes a channel region coupled to and controllable by a gate structure. The gate structure includes a gate dielectric layer on and surrounding the channel region and a gate electrode on the gate dielectric layer and surrounding the channel, to provide a gate all around (GAA) transistor. Each gate electrode is independently controllable. As used herein, the term gate structure indicates an electrode coupled to a channel of a semiconductor structure and is inclusive of gate structures including a gate dielectric on the semiconductor structure and a gate electrode on the gate dielectric. Each gate electrode is separated and electrically isolated from neighboring ones of the gate electrodes by an isolation layer that is on each one of the neighboring gate electrode. For example, first and second gate electrodes are neighboring when there is no intervening gate electrode, and the first and second gate electrodes are separated by an isolation layer sandwiched between the first and second gate electrodes, with no other intervening material between the first and second gate electrodes and the isolation layer.

In some embodiments, the multi-transistor structure includes vertically aligned semiconductor structures of differing conductivity type. For example, one or more of the semiconductor structures may be p-type semiconductor material and one or more of the semiconductor structures may be n-type semiconductor material. As used herein, the term p-type semiconductor material indicates a semiconductor material doped with hole carriers (acceptor dopants), with exemplary dopant materials including boron, aluminum, gallium, and indium. The term n-type semiconductor material indicates a semiconductor material doped with electron carriers (donor dopants), with exemplary dopant materials including phosphorous, arsenic, antimony, and bismuth. Other material systems may be used. In such contexts, different gate electrode metals may be used corresponding to the conductivity type of the semiconductor structures. Furthermore, different isolation materials may be used in such contexts.

Furthermore, in some embodiments, a conductor may be fabricated such that the conductor is between two adjacent ones of the semiconductor structures. The conductor may be characterized as an inter-ribbon connection, for example. The conductor is separated from adjacent ones of the gate electrodes by isolation materials. The conductor may traverse the multi-transistor structure for interconnection of devices in the device. For example, the conductor may couple to a gate, source, or drain of one or more of the transistors in a first multi-transistor structure and extend between semiconductor structures (and gate electrodes, and sources and drains) of a second multi-transistor structure to bypass the second multi-transistor structure. Such bypass conductors or inter-ribbon connections provide flexibility in coupling transistors and other devices, and other advantages.

As discussed, an IC die including multi-transistor structures may be deployed in a very low temperature context. In some embodiments, the operating temperature of the IC die is maintained at or below 0° C. In some embodiments, the operating temperature of the IC die is maintained at or below about −196° C. (i.e., using liquid nitrogen as the coolant). In some embodiments, the operating temperature of the IC die is maintained at or below about −25° C. In some embodiments, the operating temperature of the IC die is maintained at or below about −50° C. In some embodiments, the operating temperature of the IC die is maintained at or below about −70° C. In some embodiments, the IC die is maintained at or below about −100° C. Other temperatures may be used based on coolant, environment, and so on. In operation at such very low temperatures, the single semiconductor structures may exhibit a substantial boost in performance relative to operation at higher temperatures inclusive of increased carrier mobility, reduced contact resistance, and reduced leakage. Furthermore, such very low temperature deployment may allow for reduced semiconductor structure size and further multi-transistor device efficiency.

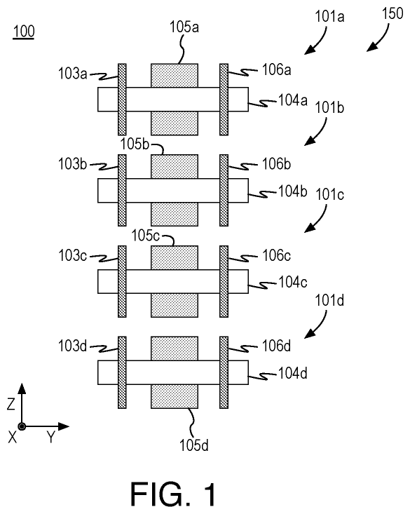

FIG. 1 illustrates a cross-sectional view of an example multi-transistor structure device 100, arranged in accordance with at least some implementations of the present disclosure. As shown in FIG. 1, a multi-transistor structure 150 includes a number of transistors 101a-d such that transistors 101a-d are vertically aligned. Herein, the term vertical is with respect to the z-axis and the term aligned indicates at least a portion of such structures are aligned in the pertinent direction or axis. The term fully aligned indicates an entirety of such structures are aligned in the pertinent direction or axis.

For example, multi-transistor structure 150 includes transistor 101a, which includes a semiconductor structure 104a, a gate electrode 105a, a source structure 103a, and a drain structure 106a. In some embodiments, transistor 101a includes a gate dielectric between gate electrode 105a and semiconductor structure 104a, as discussed further herein below. Furthermore, as also discussed herein below, the portion of semiconductor structure 104a surrounded by gate electrode 105a may be characterized as a channel region or channel structure. Also as shown in FIG. 1, transistor 101b includes a semiconductor structure 104b, a gate electrode 105b, a source structure 103b, and a drain structure 106b; transistor 101c includes a semiconductor structure 104c, a gate electrode 105c, a source structure 103c, and a drain structure 106c; transistor 101c includes a semiconductor structure 104c, a gate electrode 105c, a source structure 103c, and a drain structure 106c; and so on. Although illustrated with four transistors in multi-transistor structure 150, any number of transistors may be stacked such as three, four, five, tens, or even a hundred or more transistors.

Notably, multi-transistor structure 150 includes vertically aligned semiconductor structures 104a-d. In some embodiments, semiconductor structures 104a-d are semiconductor nanoribbons, nanosheets, fins, or the like, fabricated based on etch of sacrificial material layers between the desired semiconductor structure layers. Semiconductor structures 104a-d may include any suitable semiconductor material. In some embodiments, semiconductor structures 104a-d include a Group IV material (e.g., silicon). In some embodiments, semiconductor structures 104a-d include a substantially monocrystalline material. Semiconductor structures 104a-d layers 104 may include any number of channel semiconductors, ribbons, or layers over the substrate such as three, four, five, tens, or even a hundred or more layers. In some embodiments, semiconductor structures 104a-d include silicon (e.g., monocrystalline silicon, Si) and the removed sacrificial layers include silicon germanium.

Semiconductor structures 104a-d may have any suitable dimensions. In some embodiments, semiconductor structures 104a-d have a thickness (i.e., in the z-dimension) in the range of 0.5 to 20 nm. In some embodiments, semiconductor structures 104a-d have a thickness in the range of 0.5 to 10 nm. In some embodiments, semiconductor structures 104a-d have a thickness in the range of 8 to 20 nm. In particular, as discussed herein, multi-transistor structure device 100 may advantageously be operated at very cold temperatures such that transistors 101a— d operate efficiently with low leakage, high mobility, and other advantages. Such very cold temperatures may allow for efficient operation of semiconductor structures 104a-d having reduced thicknesses. In some embodiments, semiconductor structures 104a-d have a thickness of not more than 2 nm. In some embodiments, semiconductor structures 104a-d have a thickness of not more than 2 nm and a cooling structure is used to remove heat from an IC die including multi-transistor structure device 100 to achieve an operating temperature of the IC die at or below −25° C.

As shown, each of semiconductor structures 104a-d is contacted by an independent gate electrode 105a-d. As used herein, the term independent with respect to an electrical component such as a gate structure or electrode, a source structure, a drain structure, or the like indicates the component is separately controllable. In this context, each gate electrode provides a separately controllable transistor. Such gate electrodes 105a-d are separated by gaps filled with an isolation material as discussed further herein below. The isolation may be any amorphous material suitable for providing electrical isolation. In some embodiments, the isolation is silicon dioxide. Other known dielectric materials may also be employed such as carbon-doped oxides, siloxane derivatives, and the like.

Gate electrodes 105a-d may each be part of a gate structure that includes a gate dielectric (not shown in FIG. 1) on a channel portion of a corresponding one of semiconductor structures 104a-d and one of gate electrodes 105a-d on the gate dielectric. The gate dielectric may include one layer or a stack of layers including silicon oxide, silicon dioxide (SiO₂), and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Each gate electrode of gate electrodes 105a-d is formed on the gate dielectric layer and may consist of at least one p-type work function metal or n-type work function metal, depending on whether the transistor is to be a PMOS or an NMOS transistor. In some embodiments, the gate electrode may consist of a stack of two or more metal layers, where one or more metal layers are work function metal layers and at least one metal layer is a fill metal layer. For a PMOS transistor, metals that may be used for the gate electrode include, but are not limited to, ruthenium, palladium, platinum, cobalt, nickel, and conductive metal oxides, e.g., ruthenium oxide. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. In some embodiments, one or more of semiconductor structures 104a-d are n-type semiconductor materials and one or more of semiconductor structures 104a-d are p-type semiconductor materials. In such embodiments, the materials of the corresponding ones of gate electrodes 105a-d may be selected based on the conductivity type of semiconductor structures 104a-d.

Furthermore, each of semiconductor structures 104a-d is contacted by an independent source structure 103a-d and an independent drain structure 106a-d. Such source structures 103a— d and drain structures 106a-d are also separated by gaps filled with isolation material, which may be the same or differing material with respect to the isolation material separating gate electrodes 105a-d.

In some embodiments, source structures 103a-d and drain structures 106a-d are formed using an epitaxial deposition process such that source structures 103a-d and drain structures 106a-d are epitaxial to semiconductor structures 104a-d. For example, source structures 103a-d and drain structures 106a-d may share a crystalline orientation with semiconductor structures 104a-d. In some embodiments, source structures 103a-d and drain structures 106a-d are fabricated using a silicon alloy such as silicon germanium or silicon carbide. In some embodiments, the epitaxially deposited silicon alloy may be doped in situ with dopants such as boron, arsenic, or phosphorous. In further embodiments, source structures 103a-d and drain structures 106a-d may be formed using one or more alternate semiconductor materials such as germanium or a group III-V material or alloy. And in further embodiments, one or more layers of metal and/or metal alloys may be used to form source structures 103a-d and drain structures 106a-d. In some embodiments, one or more of semiconductor structures 104a-d are n-type semiconductor materials and one or more of semiconductor structures 104a-d are p-type semiconductor materials. In such embodiments, the materials of the corresponding ones of source structures 103a-d and drain structures 106a-d may be selected based on the conductivity type of semiconductor structures 104a-d.

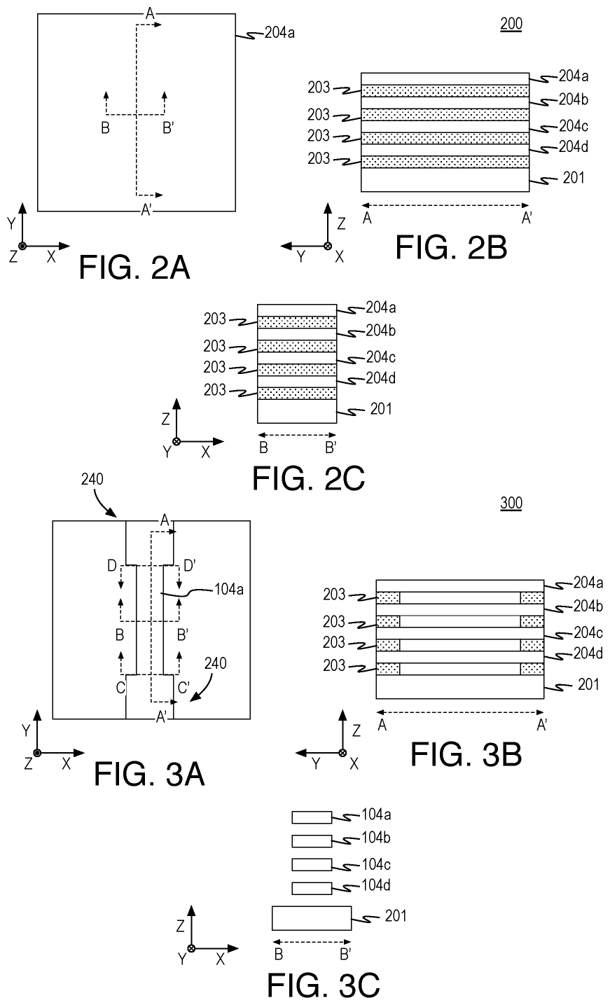

FIGS. 2A, 2B, 2C, 3A, 3B, 3C, and 4-17 illustrate example multi-transistor structures as selected fabrication operations are performed, arranged in accordance with at least some implementations of the present disclosure. FIG. 2A is a top down view of an example multi-transistor structure 200, FIG. 2B is a cross-sectional view of multi-transistor structure 200 taken at cross-section A-A′ (an along the channel cross section), and FIG. 2C is a cross-sectional view of multi-transistor structure 200 taken at cross-section B-B′ (an across the channel cross section).

As shown in FIGS. 2A-C, multi-transistor structure 200 includes a multilayer stack of any number of interleaved semiconductor material layers 204a-d and sacrificial layers 203. For example, semiconductor material layers 204a-d, as shown in FIGS. 2A-C include bulk material layers of the materials that will be patterned into semiconductor structures 104a-d. Semiconductor material layers 204a-d may include any materials and thicknesses discussed with respect to semiconductor structures 104a-d. Although illustrated with respect to four semiconductor material layers 204a-d, any number of semiconductor material layers 204a-d may be deployed such as three, four, five, tens, or even a hundred or more semiconductor material layers 204a-d. Sacrificial layers 203 include materials selected to have high etch selectively with respect to semiconductor material layers 204a-d such that sacrificial layers 203 may be removed while semiconductor material layers 204a-d remain. In some embodiments, semiconductor material layers 204a-d are silicon layers and sacrificial layers 203 are germanium or silicon germanium layers, however, any suitable sacrificial layers and etch selective materials may be deployed.

In some embodiments, each of semiconductor material layers 204a-d include the same semiconductor materials and conductivity types. For example, each of semiconductor material layers 204a-d may be n-type semiconductor material using any dopants discussed herein. In some embodiments, each of semiconductor material layers 204a-d is a p-type semiconductor material using any dopants discussed herein. In some embodiments, one or more of semiconductor material layers 204a-d are p-type semiconductor material and one or more of semiconductor material layers 204a-d are n-type semiconductor material. Using such techniques, eventual transistors 101a-d may include NMOS and PMOS transistors in close proximity such that they are stacked in the same multi-transistor structure.

Such p-type and n-type semiconductor material layers may be arranged in any suitable manner. In some embodiments, n-type semiconductor material layers are interleaved with p-type semiconductor material layers such p-type and n-type semiconductor material layers alternate in the stack. For example, semiconductor material layers 204a may be n-type, semiconductor material layers 204b may be p-type, semiconductor material layers 204c may be n-type, semiconductor material layers 204d may be p-type, or vice versa. In some embodiments, all semiconductor material layers 204 at a top of the stack are of one conductivity type and those at the bottom are of the other conductivity type. For example, semiconductor material layers 204a, b may be n-type and semiconductor material layers 204c,d may be p-type, or vice versa. Although such examples offer particular advantages such as high density and/or ease of access, other patterns may be used.

Semiconductor material layers 204a and sacrificial layers 203 may be formed using any suitable technique or techniques such as chemical vapor deposition (CVD), metalorganic chemical vapor deposition (MOCVD), atomic layer deposition (ALD), molecular beam epitaxy (MBE), or others. Substrate 201 may include any suitable material or materials. For example, substrate 201 may be a substrate substantially aligned along a predetermined crystal orientation (e.g., (100), (111), (110), or the like). In some examples, substrate 201 may include a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. In some examples, substrate 201 may include silicon having a (100) crystal orientation with a 4°-11° miscut (with 4°-6° being particularly advantageous). Examples using silicon having a crystal orientation of (110) or (111) may offer the advantage of having a smaller mismatch for subsequent epitaxial growth. For example, substrate 201 may be (111) silicon, (100) silicon, or (110) silicon. In an embodiment, substrate 201 includes a (111) crystalline group IV material. In various examples, substrate 201 may include metallization interconnect layers for integrated circuits or electronic devices such as transistors, memories, capacitors, resistors, optoelectronic devices, switches, or any other active or passive electronic devices separated by an electrically insulating layer, for example, an interlayer dielectric, a trench insulation layer, or the like.

FIG. 3A is a top down view of an example multi-transistor structure 300, FIG. 3B is a cross-sectional view of multi-transistor structure 300 taken at cross-section A-A′ (an along the channel cross section), and FIG. 3C is a cross-sectional view of multi-transistor structure 300 taken at cross-section B-B′ (an across the channel cross section). Cross-sections C-C′ and D-D′ referenced herein below. Multi-transistor structure 300 is similar to multi-transistor structure 200, after the patterning of semiconductor material layers 204a-d and removal of at least portions of sacrificial layers 203 to form semiconductor structures 104a-d.

As shown, semiconductor structures 104a-d are vertically aligned and extend in a lateral direction (i.e., the y-direction) to provide semiconductor nanowires, nanoribbons, nanosheets, or fins or the like for the eventual fabrication of transistors 101a-d. For example, semiconductor structures 104a-d may be characterized as any of nanowires, nanoribbons, nanosheets, or fins, etc. depending on the cross-sectional aspect ratio of semiconductor structures 104a-d or other features. For example, semiconductor structures 104a-d having a 1:1 cross-sectional aspect ratio may be labeled as nanowires or nanoribbons, semiconductor structures 104a-d having a greater x-dimension than z-dimension may be labeled as nanosheets or nanoribbons, and semiconductor structures 104a-d having a greater z-dimension than x-dimension may be labeled as fins, for example. In any event, as discussed herein below, such semiconductor structures 104a-d provide for vertically aligned semiconductor materials for fabrication of independent gate all around devices.

Multi-transistor structure 300 may be formed using any suitable technique or techniques. In some embodiments, semiconductor structures 104a-d and sacrificial layers 203 are patterned using lithography and etch techniques. Subsequently, at least portions of sacrificial layers 203 may be removed using selective etch techniques. In some embodiments, multi-transistor structure 300 includes anchor structures 240 to support the suspension of semiconductor structures 104a-d. In some embodiments, sacrificial layers 203 remain within anchor structures 240 to provide support for semiconductor structures 104a-d. Such sacrificial layers may be retained in anchor structures 240 by at masking anchor structures 240 during the selective etch, using timed selective etch techniques, or the like. Other anchor structures may be used.

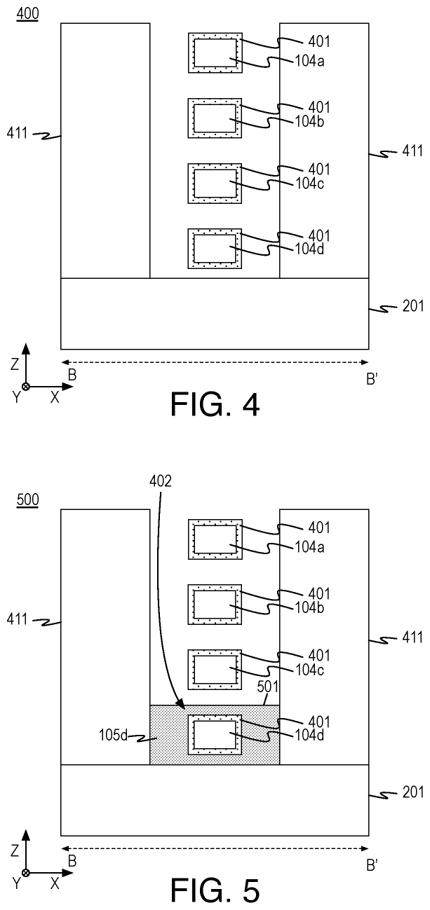

FIG. 4 is a cross-sectional view of an example multi-transistor structure 400 similar to multi-transistor structure 300 after the formation of gate dielectric layers, arranged in accordance with at least some implementations of the present disclosure. In FIGS. 4-9, cross-sectional views taken at cross-section B-B′ are illustrated while top down views and cross-sectional views taken at cross-section A-A′ are not illustrated for the sake of brevity and clarity of presentation. As shown, a gate dielectric layer 401 is formed on each of semiconductor structures 104a-d. Gate dielectric layers 401 may include any material discussed herein. For example, each of gate dielectric layers 401 may be a single layer or a stack of layers including silicon oxide, silicon dioxide, and/or a high-k dielectric material, as discussed herein. Also as shown, in some embodiments, multi-transistor structure 400 includes isolation structures 411 to provide a template for formation of isolated gate structures as discussed herein. In some embodiments, isolation structures 411 are not deployed and, instead, the resultant gate structures are patterned using lithography and etch techniques for example.

Gate dielectric layers 401 may be formed using any suitable technique or techniques such as atomic layer deposition, plasma enhanced atomic layer deposition, or others. As shown, gate dielectric layers 401 may be substantially conformal to each of semiconductor structures 104a-d. In some embodiments, gate dielectric layers 401 are formed selectively on each of semiconductor structures 104a-d. In some embodiments, gate dielectric layers 401 may also form on substrate 201 and/or isolation structures 411.

FIG. 5 is a cross-sectional view of an example multi-transistor structure 500 similar to multi-transistor structure 400 after the formation of a first gate electrode, arranged in accordance with at least some implementations of the present disclosure. As shown, gate electrode 105d is formed such that gate electrode 105d (and gate dielectric layer 401 on semiconductor structure 104d) surround a channel region 402 of semiconductor structure 104d. Notably, gate dielectric layer 401 on semiconductor structure 104d surrounds channel region 402 of semiconductor structure 104d, and gate electrode 105d is on gate dielectric layer 401 of semiconductor structure 104d and surrounding channel region 402 of semiconductor structure 104d. As discussed, channel region 402 may be a region of semiconductor structure 104d controllable by gate electrode 105d.

As shown, gate electrode 105d does not couple to or surround any of semiconductor structures 104a-c. Thereby, gate electrode 105d is operable to control only transistor 101d while not being operable to control transistors 101a-c. As shown, gate electrode 105d has a top surface 501 that is between semiconductor structure 104d and semiconductor structure 104c. Gate electrode 105d may be formed using any suitable technique or techniques such as chemical vapor deposition, molecular beam epitaxy, electron beam physical vapor deposition, or the like. In some embodiments, a bulk metal is formed and a recess is performed to provide gate electrode 105d. Gate electrode 105d may include any material discussed herein. In some embodiments, the material of gate electrode 105d is selected in accordance with the conductivity type of semiconductor structure 104d. In some embodiments, gate electrode 105d includes a stack of two or more metal layers with one or more work function metal layers and one or more fill metal layers. For a p-type semiconductor structure 104d, metals that may be used for the gate electrode include, but are not limited to, ruthenium, palladium, platinum, cobalt, nickel, and conductive metal oxides, e.g., ruthenium oxide. For an n-type semiconductor structure 104d, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide.

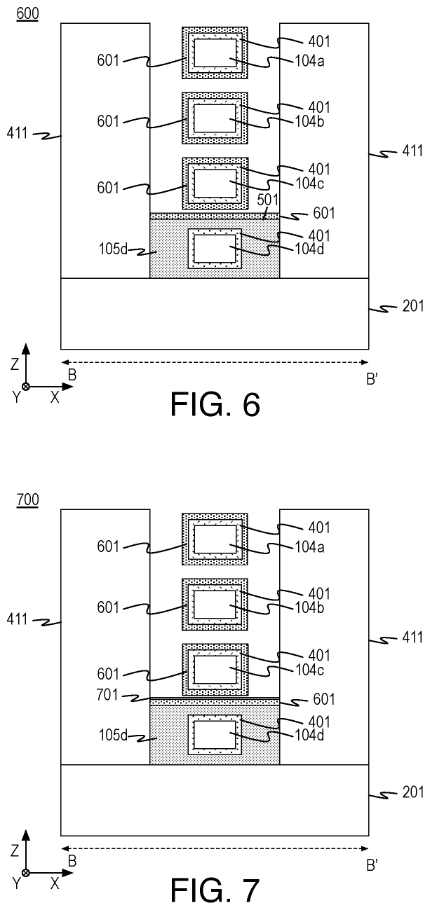

FIG. 6 is a cross-sectional view of an example multi-transistor structure 600 similar to multi-transistor structure 500 after formation of a gate electrode isolation layer, arranged in accordance with at least some implementations of the present disclosure. As shown, isolation layers 601 are formed on each gate dielectric layer on semiconductor structures 104a-c (i.e., the exposed semiconductor structures 104a-c) and on top surface 501 of gate electrode 105d. Isolation layers 601 may include any suitable dielectric material having an etch selectivity with respect to gate dielectric layers 401. For example, isolation layers 601 may be any amorphous material suitable for providing electrical isolation. In some embodiments, isolation layers 601 include silicon dioxide. In some embodiments, isolation layers 601 includes one or more of silicon oxide, alumina, silicon nitride, silicon oxynitride, or silicon carbonitride. Other known dielectric materials may also be employed such as carbon-doped oxides, siloxane derivatives, and the like.

Isolation layers 601 may be formed using any suitable technique or techniques such as atomic layer deposition, plasma enhanced atomic layer deposition, or others. As shown, isolation layers 601 may be substantially conformal to each of semiconductor structures 104a-c. In some embodiments, isolation layer 601 may also form on isolation structures 411.

FIG. 7 is a cross-sectional view of an example multi-transistor structure 700 similar to multi-transistor structure 700 after the formation of an optional protective layer, arranged in accordance with at least some implementations of the present disclosure. As shown, a protective layer 701 may be formed on the isolation layer 601 on gate electrode 105d using directional deposition techniques, deposition and timed etch techniques, or the like. It is noted, protective layer 701 may also be formed on other top surfaces, but such residuals may be removed during subsequent etch operations. Protective layer 701 may also provide a seed layer for subsequent metal deposition. Protective layer 701 may include any gate electrode material or metal discussed herein.

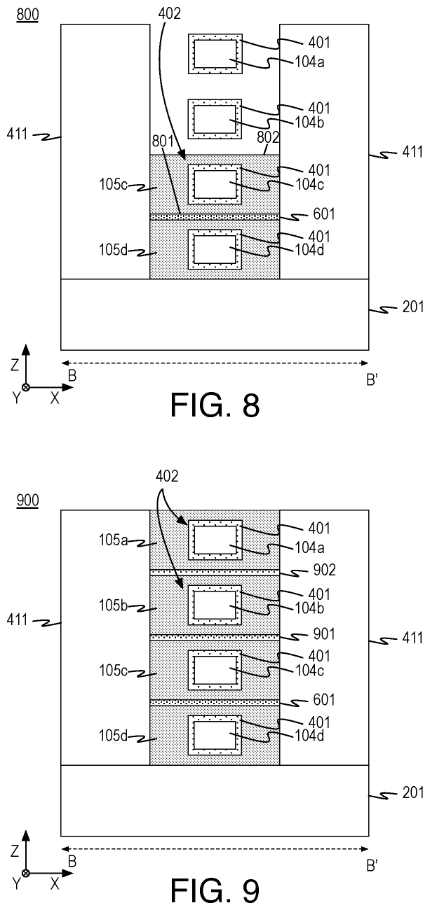

FIG. 8 is a cross-sectional view of an example multi-transistor structure 800 similar to multi-transistor structure 700 after the removal of exposed isolation layers and the formation of a second gate electrode, arranged in accordance with at least some implementations of the present disclosure. As shown, the exposed isolation layers 601 (i.e., isolation layers 601 on gate dielectric layers 401 on semiconductor structures 104a-c) are removed to expose gate dielectric layers 401 on semiconductor structures 104a-c. The exposed isolation layers 601 may be removed using any suitable technique or techniques such as selective etch techniques.

Subsequent to the removal of the exposed isolation layers 601, gate electrode 105c is formed such that gate electrode 105c (and gate dielectric layer 401 on semiconductor structure 104c) surrounds a channel region 402 of semiconductor structure 104c. Notably, gate dielectric layer 401 on semiconductor structure 104c surrounds channel region 402 of semiconductor structure 104c, and gate electrode 105c is on gate dielectric layer 401 of semiconductor structure 104c and surrounding channel region 402 of semiconductor structure 104c. Channel region 402 is a region of semiconductor structure 104c controllable by gate electrode 105c.

Gate electrode 105c does not couple to or surround any of semiconductor structures 104a, b, d. Thereby, gate electrode 105c is operable to control only transistor 101c while not being operable to control transistors 101a, b, d. Gate electrode 105c has a bottom surface 801 that is between semiconductor structure 104d and semiconductor structure 104c, and a top surface 802 that is between semiconductor structure 104b and semiconductor structure 104c. Gate electrode 105c may be formed using any suitable technique or techniques discussed with respect to the formation of gate electrode 105d. Gate electrode 105c may include any material discussed herein. In some embodiments, the material of gate electrode 105c is selected in accordance with the conductivity type of semiconductor structure 104c as discussed with respect to gate electrode 105d. For example, the materials of gate electrode 105c and gate electrode 105d may be the same or they may be different.

FIG. 9 is a cross-sectional view of an example multi-transistor structure 900 similar to multi-transistor structure 800 after repeated isolation layer formation and gate electrode formation processing, arranged in accordance with at least some implementations of the present disclosure. As shown, the processing discussed with respect to FIGS. 6-8 may be repeated any number of times to form isolation layers 601, 901, 902 and gate electrodes 105a-d. For example, such processing may be repeated for each of any remaining semiconductor structures.

As discussed, semiconductor structures 104a-d may be the same materials or they may be different. For example, the techniques discussed herein offer the flexibility of closely packing transistors of differing characteristics. In some embodiments, one or more of semiconductor structures 104a-d are of a first conductivity type and one or more of semiconductor structures 104a-d are of a second conductivity type. Furthermore, semiconductor structures 104a-d of the same conductivity type may have the same or differing material compositions. In some embodiments, one or more of semiconductor structures 104a-d are of a first conductivity type and one or more of semiconductor structures 104a-d are of the same first conductivity type but with a greater dopant concentration and/or differing dopant materials. For example, one or more p-type semiconductor structures 104a-d may include one of boron, aluminum, gallium, and indium while one or more other p-type semiconductor structures 104a-d may include another one of boron, aluminum, gallium, and indium. In some embodiments the same dopants are used but at differing concentrations and/or differing combinations of dopants may be used. Similarly, one or more n-type semiconductor structures 104a-d may include one of phosphorous, arsenic, antimony, and bismuth while one or more other p-type semiconductor structures 104a-d may include another one of phosphorous, arsenic, antimony, and bismuth, or other combinations, or chemistries.

In addition or in the alternative, the same material choices may be deployed with respect to gate electrodes 105a-d. For example, the material choice may be made based on the conductivity type and composition of semiconductor structures 104a-d. For example, gate electrodes 105a-d may deploy differing material stacks, compositions, etc. depending on the conductivity type of semiconductor structures 104a-d and the material compositions of semiconductor structures 104a-d. Furthermore, isolation layers 601, 901, 902 may be the same or they may be different. For example, the material compositions of isolation layers 601, 901, 902 may be selected based on the materials of gate electrodes 105a-d they are providing isolation between with differing isolation materials providing various advantages such as dielectric properties, adhesion properties, potential contamination, and so on.

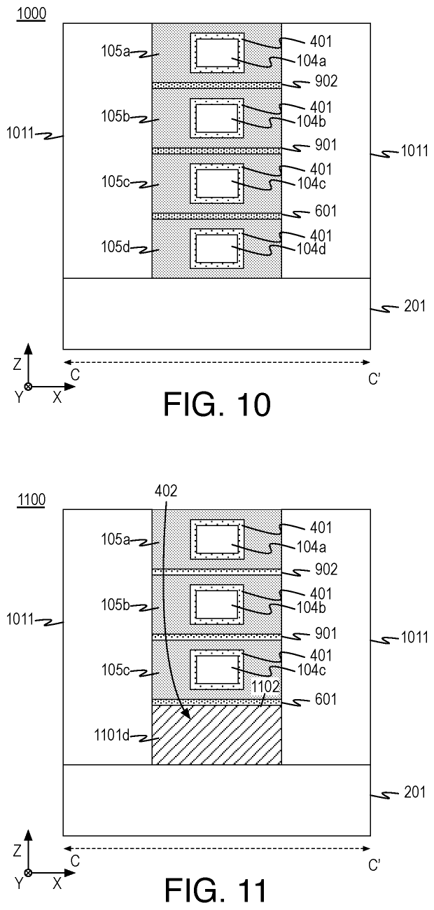

Discussion now turns to fabrication of independent source and drain structures, which may be performed in a manner similar to the fabrication of independent gate structures. With reference to FIG. 3A, FIG. 10 is a cross-sectional view of multi-transistor structure 900 or 300 taken at cross-section C-C′ (an across the channel cross section looking at the source/drain) after exposing end portions of semiconductor structures 104a-d to form multi-transistor structure 1000. Notably, a same or similar view is present at cross-section D-D′ with only cross-section C-C′ being illustrated for the sake of clarity and brevity. For example, source and drain structures may be formed using the same operations.

As shown with respect to multi-transistor structure 1000 in FIG. 10, end portions of semiconductor structures 104a-d are exposed by, for example, removal of anchor structures 240. Such removal of anchor structures 240 may be performed using any suitable technique or techniques such as lithography and etch techniques. Such etching of anchor structures 240 may be performed subsequent to formation of gate structures, for example, such that semiconductor structures 104a-d are supported by the fabricated gate structures. In some embodiments, multi-transistor structure 400 includes optional isolation structures 1011 in analogy with isolation structures 411 to provide a template for formation of isolated gate structures as discussed herein. In some embodiments, isolation structures 1011 are not deployed.

FIG. 11 is a cross-sectional view of an example multi-transistor structure 1100 similar to multi-transistor structure 1000 after the formation of a first source or drain, arranged in accordance with at least some implementations of the present disclosure. In the context of FIGS. 11-13, sources and drains are formed at opposite ends of semiconductor structures 104a-d (i.e., at cross-sections C-C′ and D-D′). As shown, source or drain 1101d is formed such that source or drain 1101d is epitaxial to semiconductor structure 104d. Moving forward in the y-dimension, source or drain 1101d interfaces with channel region 402 of semiconductor structure 104d with channel region 402 being obscured in the view of FIG. 11. For example, channel region 402 is contacted by an independent source, drain and gate electrode.

As shown, source or drain 1101d does not couple any of semiconductor structures 104a-c. Thereby, source or drain 1101d is operable to be a supply or an output (drain) of transistor 101d while not being coupled to transistors 101a-c. As shown, source or drain 1101d has a top surface 1102 that is between semiconductor structure 104d and semiconductor structure 104c. Source or drain 1101d may be formed using any suitable technique or techniques such as epitaxial growth and etch techniques. For example, epitaxial growth may grow epitaxial materials from all of exposed semiconductor structures 104a-d, and the material may be removed from and adjacent to semiconductor structures 104a-c.

Source or drain 1101d may include any material discussed herein. In some embodiments, source or drain 1101d includes a silicon alloy such as silicon germanium or silicon carbide. In some embodiments, the epitaxially deposited silicon alloy may be doped in situ with dopants such as boron, arsenic, or phosphorous. In some embodiments, source or drain 1101d include germanium or a group III-V material or alloy. In some embodiments, one or more of semiconductor structures 104a-d are n-type semiconductor materials and one or more of semiconductor structures 104a-d are p-type semiconductor materials. In such embodiments, the materials of source or drain 1101d may be selected based on the conductivity type of semiconductor structure 104d.

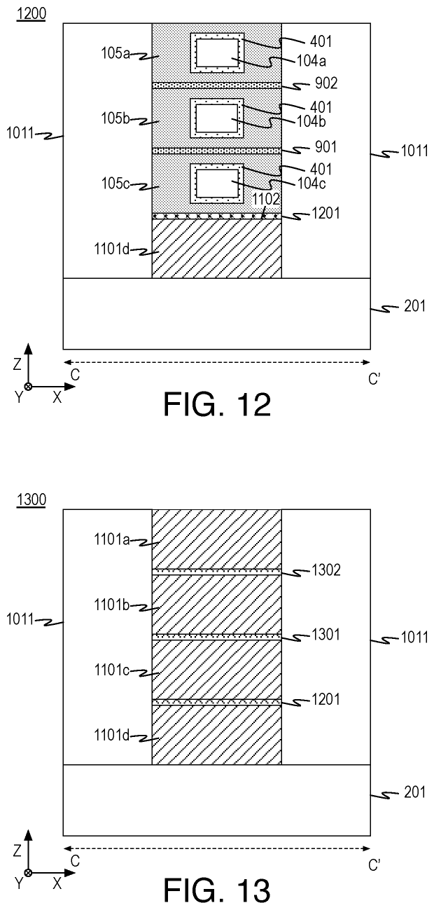

FIG. 12 is a cross-sectional view of an example multi-transistor structure 1200 similar to multi-transistor structure 1100 after formation of a source or drain isolation layer, arranged in accordance with at least some implementations of the present disclosure. As shown, isolation layer 1201 is formed on source or drain 1101d (i.e., top surface 1102 of source or drain 1101d). Isolation layer 1201 may include any suitable dielectric material such as amorphous material suitable for providing electrical isolation. In some embodiments, isolation layer 1201 includes silicon dioxide. In some embodiments, isolation layer 1201 includes one or more of silicon oxide, alumina, silicon nitride, silicon oxynitride, or silicon carbonitride. Other known dielectric materials may also be employed such as carbon-doped oxides, siloxane derivatives, and the like.

Isolation layer 1201 may be formed using any suitable technique or techniques such as atomic layer deposition, plasma enhanced atomic layer deposition, or others. In some embodiments, isolation layer 1201 is formed by directional deposition and/or deposition and directional etch techniques.

FIG. 13 is a cross-sectional view of an example multi-transistor structure 1300 similar to multi-transistor structure 1200 after repeated isolation layer formation and source or drain formation processing, arranged in accordance with at least some implementations of the present disclosure. As shown, the processing discussed with respect to FIGS. 11 and 12 may be repeated any number of times to form isolation layers 1201, 1301, 1302 and sources or drains 1101a-d. For example, such processing may be repeated for each of any remaining semiconductor structures.

As discussed, semiconductor structures 104a-d may be the same materials or they may be different. In some embodiments, one or more of semiconductor structures 104a-d are of a first conductivity type and one or more of semiconductor structures 104a-d are of a second conductivity type. Furthermore, semiconductor structures 104a-d of the same conductivity type may have the same or differing material compositions. In addition or in the alternative, the same or similar material choices may be deployed with respect to sources or drains 1101a-d. For example, the material choice may be made based on the conductivity type and composition of semiconductor structures 104a-d. For example, sources or drains 1101a-d may deploy differing material compositions, etc. depending on the conductivity type of semiconductor structures 104a-d and the material compositions of semiconductor structures 104a-d. Furthermore, isolation layers 1201, 1301, 1302 may be the same or they may be different. For example, the material compositions of isolation layers 1201, 1301, 1302 may be selected based on the materials of sources or drains 1101a-d they are providing isolation between with differing isolation materials providing various advantages such as dielectric properties, adhesion properties, potential contamination, and so on.

As shown, a multi-transistor structure device includes a number of vertically aligned semiconductor structures 104a-d, a gate dielectric layer 401 on and surrounding a channel region 402 of each of semiconductor structures 104a-d, and an independent gate electrode 105a-d on each of the gate dielectric layers 401 and surrounding each of the channel regions 402, such that the independent gate electrodes 105a-d are vertically aligned and separated by isolation layers 601, 901, 902, each isolation layer on neighboring ones of the gate electrodes. In some embodiments, the multi-transistor structure device further includes an independent source or drain 1101a-d coupled to each of the channel regions 402 of the semiconductor structures 104a— d, the independent gate sources or drains 1101a-d vertically aligned and separated by second isolation layers 1201, 1301, 1302, each second isolation layer on 1201, 1301, 1302 neighboring ones of the sources or drains 1101a-d.

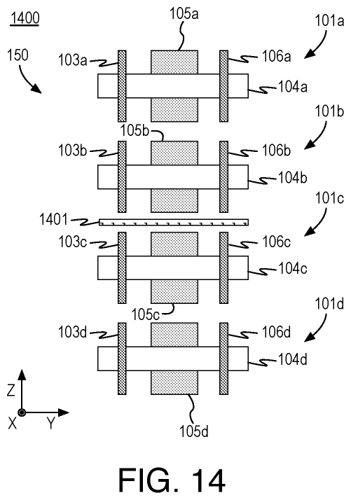

FIG. 14 illustrates a cross-sectional view of an example multi-transistor structure device 1400, arranged in accordance with at least some implementations of the present disclosure. As shown in FIG. 14, multi-transistor structure device 1400 includes multi-transistor structure 150 and a conductor 1401 between semiconductor structures 104b, c and separated from gate electrodes 205b, c by gaps filled with an isolation material as discussed further herein below. The isolation may be any amorphous material suitable for providing electrical isolation. In some embodiments, the isolation is silicon dioxide. Other known dielectric materials may also be employed such as carbon-doped oxides, siloxane derivatives, and the like.

In some embodiments, conductor 1401 also extends between sources 103b, c and/or drains 106b, c such that conductor 1401 is separated from sources 103b, c and/or drains 106b, c by gaps filled with an isolation material. In addition or in the alternative, conductor 1401 may extend laterally in the x-direction between any number of multi-transistor structures and/or laterally in the y-direction between any number of multi-transistor structures. For example, conductor 1401 may be characterized as an inter-ribbon connection and conductor 1401 may provide a piece of metal between nanowires, nanosheets, nanoribbons, or fins to provide for power or signal connections between transistors.

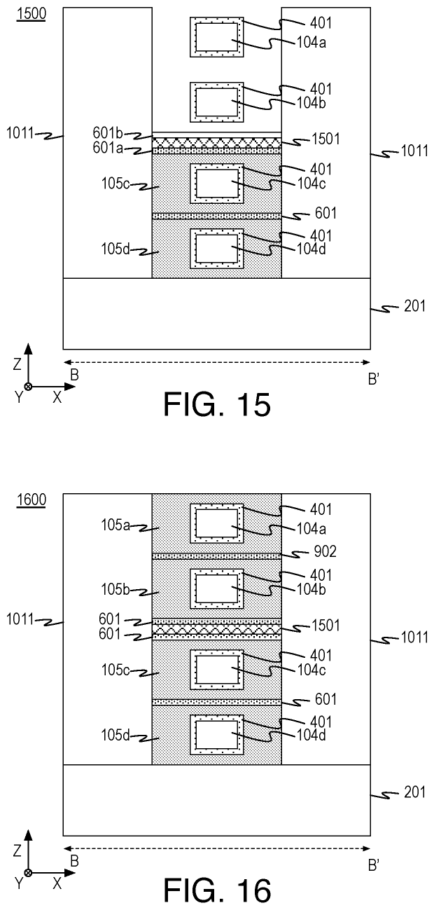

FIG. 15 is a cross-sectional view of an example multi-transistor structure 1500 similar to multi-transistor structure 800 after formation of a sacrificial layer between isolation layers, arranged in accordance with at least some implementations of the present disclosure. For example, conductor 1401 may be formed between any of semiconductor structure 104a-d using the discussed techniques. With reference to FIG. 8, multi-transistor structure 800, gate electrode 105c (and gate dielectric 401 on semiconductor structure 104c) surrounds a channel region 402 of semiconductor structure 104c. Gate electrode 105c does not couple to or surround any of semiconductor structures 104a, b, d such that gate electrode 105c is operable to control only transistor 101c while not being operable to control transistors 101a, b, d.

As shown, isolation layers 601a, b and a sacrificial layer 1501 are formed on gate electrode 105c using any suitable technique or techniques. In some embodiments, deposition and subsequent etch techniques are used to form isolation layers 601a, b and a sacrificial layer 1501. Isolation layers 601a, b may be the same materials and sacrificial layer 1501 is a material selected to have etch selectivity with respect to isolation layers 601a, b. For example, isolation layers 601a, b may be silicon oxide and sacrificial layer 1501 may be silicon nitride. Other material systems may be used such that sacrificial layer 1501 may be etched selectively with respect to isolation layers 601a, b.

FIG. 16 is a cross-sectional view of an example multi-transistor structure 1600 similar to multi-transistor structure 1500 after repeated gate electrode formation and isolation layer formation processing, arranged in accordance with at least some implementations of the present disclosure. As shown, the processing discussed with respect to FIGS. 6-8 may be repeated any number of times and in any suitable order to form gate electrodes 105a, b and isolation layer 902. For example, such processing may be repeated for each of any remaining semiconductor structures. Gate electrodes 105a, b and isolation layer 902 may be formed using any suitable technique or techniques discussed herein and may include any materials or material combinations discussed above.

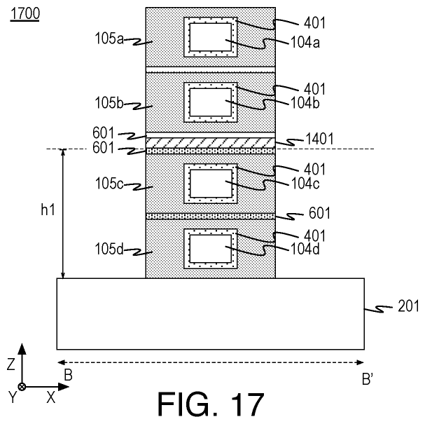

FIG. 17 is a cross-sectional view of an example multi-transistor structure 1700 similar to multi-transistor structure 1600 after removal of sacrificial layer 1501 and formation of conductor 1401. As shown, isolation structures 1011 may be recessed or removed (as shown) prior to removal of sacrificial layer 1501. Sacrificial layer 1501 may be removed using any suitable technique or techniques such as selective etch techniques to expose an opening between isolation layers 601. Subsequently, conductor 1401 is formed in the opening. Conductor 1401 may be formed using any suitable technique or techniques such as metal deposition or electroplating techniques followed by selective etch techniques. Conductor 1401 may include any suitable conductive metal such as one or more of copper, aluminum, ruthenium, palladium, platinum, cobalt, nickel, hafnium, zirconium, titanium, tungsten, or tantalum, aluminum. Other conductive materials may be deployed.

As shown, conductor 1401 is between semiconductor structures 104b, c and extends in the y-direction of the x-y plane. Conductor 1401 may further extend between sources and/or drains 1101b, c by forming a conductive layer using the same techniques. In such embodiments, conductor 1401 may be formed of segments fabricated in separate process flows. In addition or in the alternative, conductor 1401 may extend laterally in the x-direction of the x-y plane. In some embodiments, isolation material is formed at a height, hl, which is substantially aligned with conductor 1401 and metallization may be formed on the isolation material (not shown) to interconnect conductors 1401 formed between other vertically aligned semiconductor structures 104a-d. In such embodiments, conductor 1401 may be formed of segments fabricated in separate process flows and/or conductor 1401 may be coupled to other conductors or metallizations.

Such conductors may provide inter-ribbon connections for any suitable purpose such as power delivery, signaling, or the like. The conductors or connections may be contacted by vias and/or they may be coupled to one or more of gate structures or source or drain structures of various transistors. The described conductors or connections provide interconnect flexibility and efficiency.

Discussion now turns to incorporation of the multi-transistor structures discussed herein into integrated circuit systems.

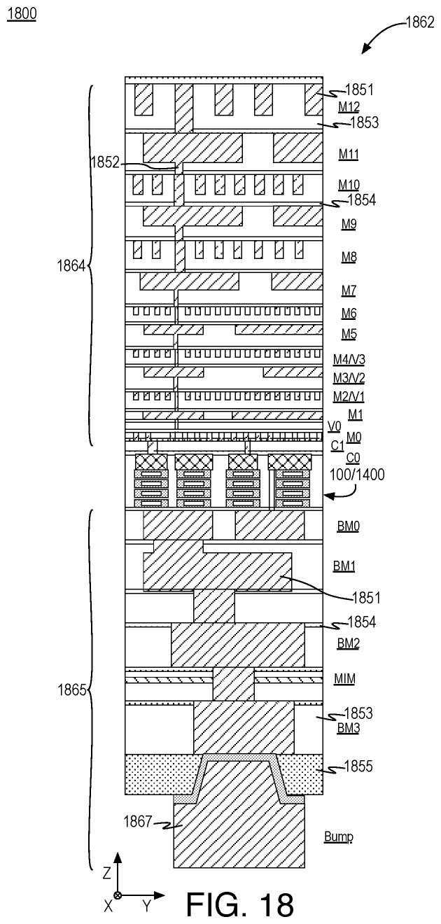

FIG. 18 illustrates a cross-sectional view of an example integrated circuit die including multi-transistor structures, arranged in accordance with at least some implementations of the present disclosure. For example, the IC die of FIG. 0.18 may include any multi-transistor structures in accordance with any structure or device discussed herein. As shown, a multi-transistor structure IC system 1800 includes multi-transistor structure device 100 or multi-transistor structure device 1400 or any other multi-transistor structure device discussed herein. In FIG. 18, a view across gate structure to semiconductor structure coupling (i.e., in the y-z plane) is shown. As shown, multi-transistor structure IC system 1800 includes front-side metallization layers 1864 (or front-side interconnect layers) and optional back-side metallization layers 1865 (or back-side interconnect layers) to form an integrated circuit (IC) die 1862. Front-side metallization layers 1864 may be formed using any suitable technique or techniques such as dual damascene techniques, single damascene techniques, subtractive metallization patterning techniques, or the like. Similarly, back-side metallization layers 1865 may be formed using any suitable technique or techniques. In some embodiments, after front-side processing, the front-side of the wafer is attached to a carrier substrate and back-side removal processing (e.g., back-side grind or etch) is used to thin the wafer. Back-side metallization layers 1865 are then formed using dual damascene, single damascene, subtractive metallization patterning, or the like.

For example, interconnectivity, signal routing, and power delivery to multi-transistor structure device 100, 1400 is provided by front-side metallization layers 1864, optional back-side metallization layers 1865, and package level interconnects 1867. In the illustrated example, package level interconnects 1867 are provided on or over a back-side of IC die 1862 as bumps over a passivation layer 1855. However, package level interconnects 1867 may be provided using any suitable interconnect structures such as bond pads, solder bumps, etc. Furthermore, in some embodiments, package level interconnects 1867 are provided on or over a front-side of IC die 1862 (i.e., over front-side metallization layers 1864) and a package level cooling structure is provided on or over a back-side of IC die.

As used herein, the term metallization layer indicates metal interconnections or wires that provide electrical routing. Adjacent metallization layers, such as metallization interconnects 1851, are interconnected by vias, such as vias 1852, that may be characterized as part of the metallization layers or between the metallization layers. In the illustrated example, front-side metallization layers 1864 include M0, V0, M1, M2/V1, M3/V2, M4/V3, and M4-M12.

However, front-side metallization layers 1864 may include any number of metallization layers such as eight or more metallization layers. Similarly, back-side metallization layers 1865 include BM0, BM1, BM2, and BM3. However, back-side metallization layers 1865 may include any number of metallization layers such as two to five metallization layers. Front-side metallization layers 1864 and back-side metallization layers 1865 are embedded within dielectric materials 1853, 1854.

As discussed the circuits and systems of the present embodiments may advantageously be deployed at very low temperatures (i.e., at or below 0° C.). Discussion now turns to exemplary very low temperature systems.

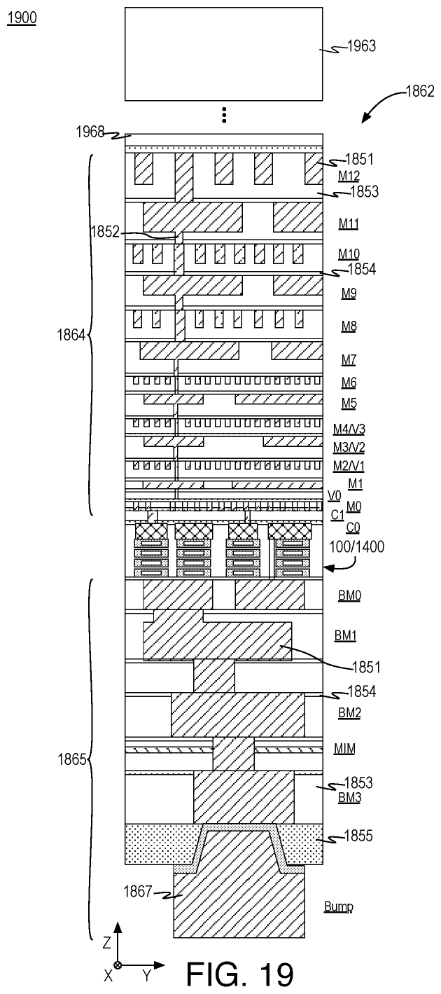

FIG. 19 illustrates a cross-sectional view of a multi-transistor structure IC system 1900 for implementation at very low temperature, arranged in accordance with at least some implementations of the present disclosure. As shown, IC system 1900 includes IC die 1862, which is a monolithic integrated circuit. IC system 1900 further includes a package level cooling structure 1963, which may be deployed on or over front-side metallization layers 1864 (as shown) or on or over a back-side of IC die 1862. In some embodiments, package level cooling structure 1963 is coupled to IC die 1862 by an adhesion layer 1968. Notably, IC system 1900 may be deployed without back-side metallization layers 1865.

IC system 1900 includes IC die 1862 and an active cooling structure operable to remove heat from IC die 1862 to achieve a very low operating temperature of IC die 1862. As used herein, the term very low operating temperature indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active cooling structure may be provided as a package level structure (i.e., separable from IC die 1862) as shown with respect to package level cooling structure 1963, as a die level structure (i.e., integral to IC die 1862), or both. In some embodiments, an active cooling structure is not needed as IC die 1862 is deployed in a sufficiently cold environment.

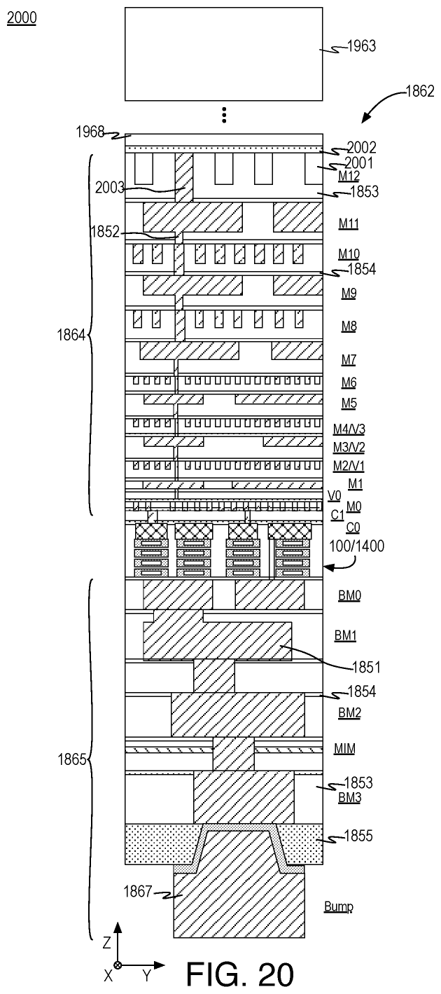

FIG. 20 illustrates a cross-sectional view of a low temperature multi-transistor structure IC system 2000 using die level cooling, arranged in accordance with at least some implementations of the present disclosure. In FIG. 20 and elsewhere herein, like numerals are used to indicate like structures or components that may have any characteristics discussed elsewhere herein. In the example of IC system 2000, IC die 1862 includes active cooling structures or components to remove heat from IC die 1862 to achieve an operating temperature of IC die 1862 at or below a target temperature such as 0° C. or any other operating or target temperature discussed herein.

In IC system 2000, IC die 1862 includes die level active cooling as provided by microchannels 2001. Microchannels 2001 are to convey a heat transfer fluid therein to remove heat from IC die 1862. The heat transfer fluid may be any suitable liquid or gas. In some embodiments, the heat transfer fluid is liquid nitrogen operable to lower the temperature of IC die to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane. The term microchannels indicates a channel to convey a heat transfer fluid with the multiple microchannels providing discrete separate channels or a network of channels. Notably, the plural microchannels does not indicate separate channel networks are needed. Such microchannels 2001 may be provided in any pattern in the x-y plane such as serpentine patterns, patterns of multiple parallel microchannels 2001, or the like. Microchannels 2001 couple to a heat exchanger (not shown) that removes heat from and cools the heat transfer fluid before re-introduction to microchannels 2001. The flow of fluid within microchannels 2001 may be provided by a pump or other fluid flow device. The operation of the heat exchanger, pump, etc. may be controlled by a controller.

In the illustrated embodiment, microchannels 2001 are implemented at metallization level M12. In other embodiments, microchannels 2001 are implemented over metallization level M12. Microchannels 2001 may be formed using any suitable technique or techniques such as patterning and etch techniques to form the void structures of microchannels 2001 and passivation or deposition techniques to form a cover structure 2002 to enclose the void structures. As shown, in some embodiments, the active cooling structure of IC system 2000 includes a number of microchannels 2001 in IC die 1862 and over a number of front-side metallization layers 1864. As discussed, microchannels 2001 are to convey a heat transfer fluid therein. In some embodiments, a metallization feature 2003 of metallization layer M12 is laterally adjacent to microchannels 2001. For example, metallization feature 2003 may couple to a package level interconnect structure (not shown) for signal routing for IC die 1862. In the example of IC system 2000, package level cooling structure 1963 may be a passive heat removal device such as a heat sink or the like. In some embodiments, package level cooling structure 1963 is not deployed in IC system 2000.

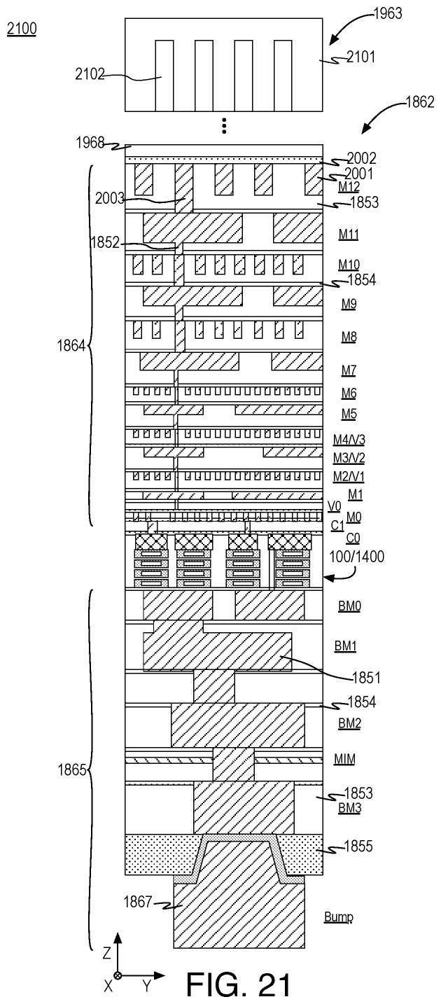

FIG. 21 illustrates a cross-sectional view of a low temperature multi-transistor structure IC system 2100 using package level cooling, arranged in accordance with at least some implementations of the present disclosure. In the example of IC system 2100, IC die 1862 includes active cooling structures or components to remove heat from IC die 1862 to achieve an operating temperature of IC die 1862 at or below a target temperature such as 0° C. or any other operating or target temperature discussed herein.

In IC system 2100, package level cooling structure 1963 includes an active cooling structure 2101 having microchannels 2102. Microchannels 2102 are to convey a heat transfer fluid therein to remove heat from IC die 1862. The heat transfer fluid may be any suitable liquid or gas as discussed with respect to FIG. 20. Microchannels 2102 may be provided in any pattern in the x-y plane such as serpentine patterns, patterns of multiple parallel microchannels 2102, etc. Microchannels 2102 couple to a heat exchanger (not shown) that removes heat from and cools the heat transfer fluid before re-introduction to microchannels 2102. The flow of fluid within microchannels 2102 may be provided by a pump or other fluid flow device. The operation of the heat exchanger, pump, etc. may be controlled by a controller. In the illustrated embodiment, active cooling structure 2101 is a chiller mounted to IC die 1862 such that the chiller has a solid body having microchannels therein to convey a heat transfer fluid.

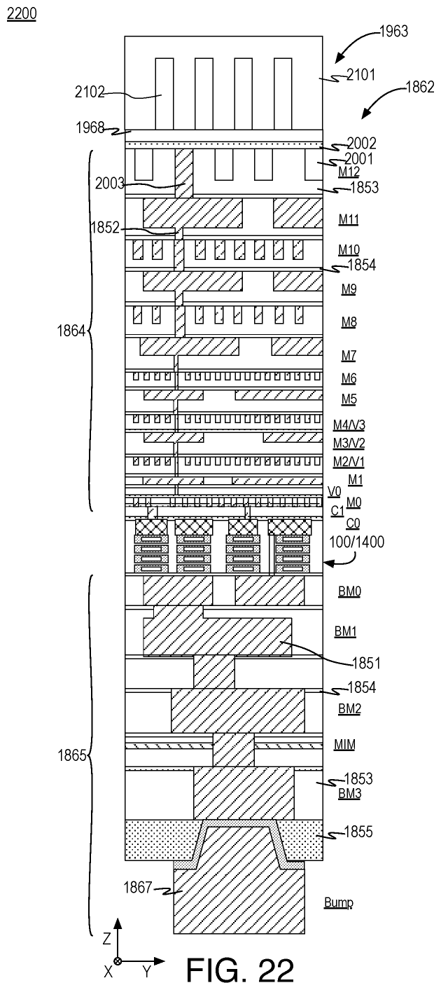

FIG. 22 illustrates a cross-sectional view of a low temperature multi-transistor structure IC system 2200 using die level and package level cooling, arranged in accordance with at least some implementations of the present disclosure. In the example of IC system 2200, IC die 1862 includes active cooling structures or components as provided by both microchannels 2001 and active cooling structure 2101.

In some embodiments, the heat removal fluid deployed in microchannels 2001 and active cooling structure 2101 are coupled to the same pump and heat exchanger systems. In such embodiments, the heat removal fluid conveyed in both microchannels 2001 and active cooling structure 2101 are the same material. Such embodiments may advantageously provide simplicity. In other embodiments, the heat removal fluids are controlled separately. In such embodiments, the heat removal fluids conveyed by microchannels 2001 and active cooling structure 2101 may be the same or they may be different. Such embodiments may advantageously provide improved flexibility.

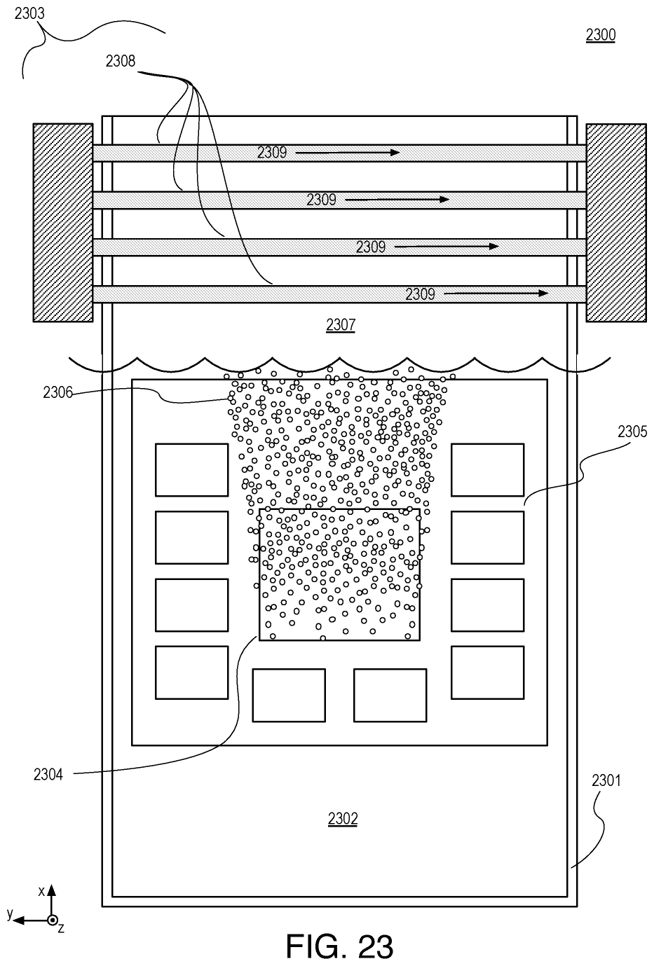

FIG. 23 illustrates a view of an example two-phase immersion cooling system 2300 for low temperature operation of an integrated circuit die having multi-transistor structures, arranged in accordance with at least some implementations of the present disclosure. As shown, two-phase immersion cooling system 2300 includes a fluid containment structure 2301, a low-boiling point liquid 2302 within fluid containment structure 2301, and a condensation structure 2303 at least partially within fluid containment structure 2301. As used herein, the term low-boiling point liquid indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 2304, such as an IC package including any of IC device as discussed herein is immersed in low-boiling point liquid 2302. In some embodiments, the IC device or system as deployed in two-phase immersion cooling system 2300 does not include additional active cooling structures, although such die level or package level active cooling structures may be used in concert with two-phase immersion cooling system 2300. In some embodiments, when deployed in two-phase immersion cooling system 2300, package level cooling structure 1963 is a heat sink, a heat dissipation plate, a porous heat dissipation plate or the like.

Notably, IC die 1862, deploying one or more functional circuit blocks having multi-transistor structures is the source of heat in the context of two-phase immersion cooling system 2300. For example, IC die 1862 may be packaged and mounted on electronics substrate 2305. Electronic substrate 2305 may be coupled to a power supply (not shown) and may be partially or completely submerged in low-boiling point liquid 2302.

In operation, the heat produced by heat generation source 2304 vaporizes low-boiling point liquid 2302 as shown in vapor or gas state as bubbles 2306, which may collect, due to gravitational forces, above low-boiling point liquid 2302 as a vapor portion 2307 within fluid containment structure 2301. Condensation structure 2303 may extend through vapor portion 2307. In some embodiments, condensation structure 2303 is a heat exchanger having a number of tubes 2308 with a cooling fluid (i.e., a fluid colder than the condensation point of vapor portion 2307) shown by arrows 2309 that may flow through tubes 2308 to condense vapor portion 2307 back to low-boiling point liquid 2302. In the IC system of FIG. 23, package level cooling structure 1963 includes a passive cooling structure such as a heat sink for immersion in low-boiling point liquid 2302.

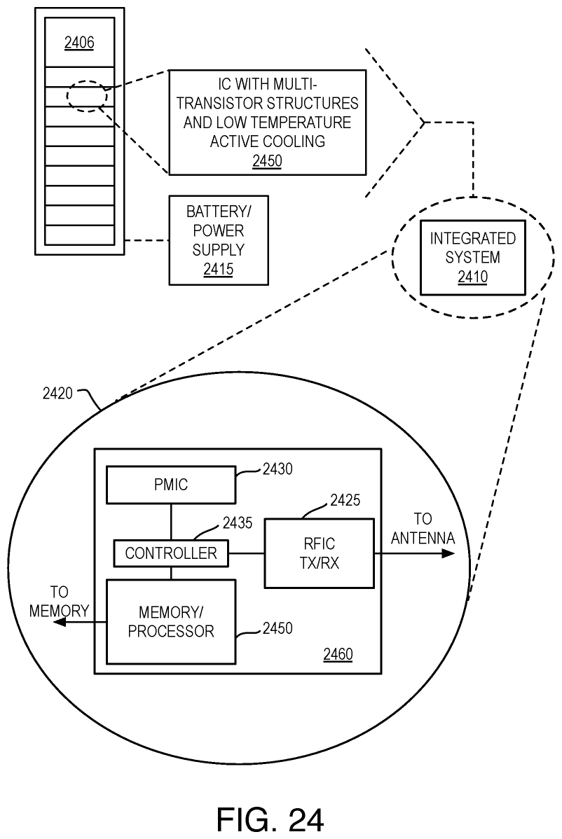

FIG. 24 illustrates diagram of an example data server machine 2406 employing a low temperature multi-transistor structure based integrated circuit system, arranged in accordance with at least some implementations of the present disclosure. Server machine 2406 may be any commercial server, for example, including any number of high-performance computing platforms disposed within a rack and networked together for electronic data processing, which in the exemplary embodiment includes one or more devices 2450 having an integrated circuit with multi-transistor structures and optional low temperature active cooling operable to remove heat from the integrated circuit to achieve any low operating temperature discussed herein.

Also as shown, server machine 2406 includes a battery and/or power supply 2415 to provide power to devices 2450, and to provide, in some embodiments power delivery functions such as power regulation. Devices 2450 may be deployed as part of a package-level integrated system 2410. Integrated system 2410 is further illustrated in the expanded view 2420. In the exemplary embodiment, devices 2450 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 2450 is a microprocessor including an SRAM cache memory. As shown, device 2450 may employ a die or device having any transistor structures and/or related characteristics discussed herein. Device 2450 may be further coupled to (e.g., communicatively coupled to) a board, a substrate, or an interposer 2460 along with, one or more of a power management integrated circuit (PMIC) 2430, RF (wireless) integrated circuit (RFIC) 2425 including a wideband RF (wireless) transmitter and/or receiver (TX/RX) (e.g., including a digital baseband and an analog front end module further comprises a power amplifier on a transmit path and a low noise amplifier on a receive path), and a controller 2435 thereof.

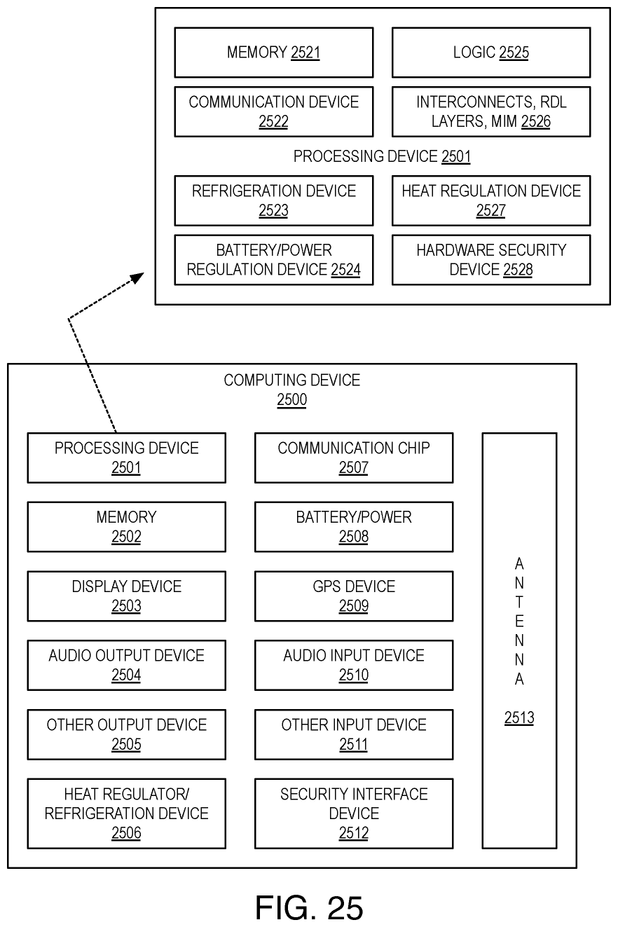

FIG. 25 is a block diagram of an example computing device 2500, arranged in accordance with at least some implementations of the present disclosure. For example, one or more components of computing device 2500 may include any of the devices or structures discussed herein. A number of components are illustrated in FIG. 25 as being included in computing device 2500, but any one or more of these components may be omitted or duplicated, as suitable for the application. In some embodiments, some or all of the components included in computing device 2500 may be attached to one or more printed circuit boards (e.g., a motherboard). In some embodiments, various ones of these components may be fabricated onto a single system-on-a-chip (SoC) die. Additionally, in various embodiments, computing device 2500 may not include one or more of the components illustrated in FIG. 25, but computing device 2500 may include interface circuitry for coupling to the one or more components. For example, computing device 2500 may not include a display device 2503, but may include display device interface circuitry (e.g., a connector and driver circuitry) to which display device 2503 may be coupled. In another set of examples, computing device 2500 may not include an audio output device 2504, other output device 2505, global positioning system (GPS) device 2509, audio input device 2510, or other input device 2511, but may include audio output device interface circuitry, other output device interface circuitry, GPS device interface circuitry, audio input device interface circuitry, audio input device interface circuitry, to which audio output device 2504, other output device 2505, GPS device 2509, audio input device 2510, or other input device 2511 may be coupled.

Computing device 2500 may include a processing device 2501 (e.g., one or more processing devices). As used herein, the term processing device or processor indicates a device that processes electronic data from registers and/or memory to transform that electronic data into other electronic data that may be stored in registers and/or memory. Processing device 2501 may include a memory 2521, a communication device 2522, a refrigeration device 2523, a battery/power regulation device 2524, logic 2525, interconnects 2526 (i.e., optionally including redistribution layers (RDL) or metal-insulator-metal (MIM) devices), a heat regulation device 2527, and a hardware security device 2528.

Processing device 2501 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Computing device 2500 may include a memory 2502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 2502 includes memory that shares a die with processing device 2501. This memory may be used as cache memory and may include embedded dynamic random-access memory (eDRAM) or spin transfer torque magnetic random-access memory (STT-M RAM).

Computing device 2500 may include a heat regulation/refrigeration device 2506. Heat regulation/refrigeration device 2506 may maintain processing device 2501 (and/or other components of computing device 2500) at a predetermined low temperature during operation. This predetermined low temperature may be any temperature discussed herein.

In some embodiments, computing device 2500 may include a communication chip 2507 (e.g., one or more communication chips). For example, the communication chip 2507 may be configured for managing wireless communications for the transfer of data to and from computing device 2500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 2507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 2507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2507 may operate in accordance with other wireless protocols in other embodiments. Computing device 2500 may include an antenna 2513 to facilitate wireless communications and/or to receive other wireless communications (such as AM or FM radio transmissions).

In some embodiments, communication chip 2507 may manage wired communications, such as electrical, optical, or any other suitable communication protocols (e.g., the Ethernet). As noted above, communication chip 2507 may include multiple communication chips. For instance, a first communication chip 2507 may be dedicated to shorter-range wireless communications such as Wi-Fi or Bluetooth, and a second communication chip 2507 may be dedicated to longer-range wireless communications such as GPS, EDGE, GPRS, CDMA, WiMAX, LTE, EV-DO, or others. In some embodiments, a first communication chip 2507 may be dedicated to wireless communications, and a second communication chip 2507 may be dedicated to wired communications.

Computing device 2500 may include battery/power circuitry 2508. Battery/power circuitry 2508 may include one or more energy storage devices (e.g., batteries or capacitors) and/or circuitry for coupling components of computing device 2500 to an energy source separate from computing device 2500 (e.g., AC line power).

Computing device 2500 may include a display device 2503 (or corresponding interface circuitry, as discussed above). Display device 2503 may include any visual indicators, such as a heads-up display, a computer monitor, a projector, a touchscreen display, a liquid crystal display (LCD), a light-emitting diode display, or a flat panel display, for example.

Computing device 2500 may include an audio output device 2504 (or corresponding interface circuitry, as discussed above). Audio output device 2504 may include any device that generates an audible indicator, such as speakers, headsets, or earbuds, for example.

Computing device 2500 may include an audio input device 2510 (or corresponding interface circuitry, as discussed above). Audio input device 2510 may include any device that generates a signal representative of a sound, such as microphones, microphone arrays, or digital instruments (e.g., instruments having a musical instrument digital interface (MIDI) output).

Computing device 2500 may include a global positioning system (GPS) device 2509 (or corresponding interface circuitry, as discussed above). GPS device 2509 may be in communication with a satellite-based system and may receive a location of computing device 2500, as known in the art.

Computing device 2500 may include other output device 2505 (or corresponding interface circuitry, as discussed above). Examples of the other output device 2505 may include an audio codec, a video codec, a printer, a wired or wireless transmitter for providing information to other devices, or an additional storage device.

Computing device 2500 may include other input device 2511 (or corresponding interface circuitry, as discussed above). Examples of the other input device 2511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2500 may include a security interface device 2512. Security interface device 2512 may include any device that provides security measures for computing device 2500 such as intrusion detection, biometric validation, security encode or decode, access list management, malware detection, or spyware detection,

Computing device 2500, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The following embodiments pertain to further embodiments.

In one or more first embodiments, a device comprises a plurality of vertically aligned semiconductor structures, a gate dielectric layer on and surrounding a channel region of each of the semiconductor structures, and an independent gate electrode on each of the gate dielectric layers and surrounding each of the channel regions, the independent gate electrodes vertically aligned and separated by isolation layers, each isolation layer on neighboring ones of the gate electrodes.

In one or more second embodiments, further to the first embodiments, the device further comprises an independent source or drain coupled to each of the channel regions of the semiconductor structures, the independent gate sources or drains vertically aligned and separated by second isolation layers, each second isolation layer on neighboring ones of the sources or drains.

In one or more third embodiments, further to the first or second embodiments, a first of the semiconductor structures comprises a p-type semiconductor material and a second of the semiconductor structures comprises an n-type semiconductor material.

In one or more fourth embodiments, further to the first through third embodiments, a first independent gate electrode coupled to the first semiconductor structure comprises a first metal composition and a second independent gate electrode coupled to the second semiconductor structure comprises a second metal composition.

In one or more fifth embodiments, further to the first through fourth embodiments, a third of the semiconductor structures adjacent to the first semiconductor structure comprises the p-type semiconductor material or a second p-type semiconductor material, and a fourth of the semiconductor structures adjacent to the second semiconductor structure comprises the n-type semiconductor material or a second n-type semiconductor material.

In one or more sixth embodiments, further to the first through fifth embodiments, a third independent gate electrode is coupled to the third semiconductor structure, and a fourth independent gate electrode is coupled to the fourth semiconductor structure, and wherein the first and third gate electrodes are separated by a first isolation layer having a first composition and the second and fourth gate electrodes are separated by a second isolation layer having a second composition.

In one or more seventh embodiments, further to the first through sixth embodiments, the device further comprises a first source or drain comprising a first material coupled to the first semiconductor structure, and a second source or drain comprising a second material coupled to the second semiconductor structure.

In one or more eighth embodiments, further to the first through seventh embodiments, the device further comprises a conductor between a first and second of the semiconductor structures, the conductor separated from the gate electrodes by isolation material, and the conductor coupled to one or more of a plurality of second vertically aligned semiconductor structures.

In one or more ninth embodiments, further to the first through eighth embodiments, the conductor extends between first and second independent sources or drains coupled to channel regions of the first and second semiconductor structures.

In one or more tenth embodiments, further to the first through ninth embodiments, the semiconductor structures comprise a plurality of nanoribbons, a plurality of nanosheets, or a plurality of fins.

In one or more eleventh embodiments, further to the first through tenth embodiments, a first of the semiconductor structures has a thickness in the vertical direction of not more than 2 nm.

In one or more twelfth embodiments, further to the first through eleventh embodiments, the device further comprises a cooling structure operable to remove heat from an IC die comprising the semiconductor structures to achieve an operating temperature at or below −25° C.

In one or more thirteenth embodiments, a system comprises an IC die having a device according to any of the first through twelfth embodiments, and a power supply coupled to the IC die.

In one or more fourteenth embodiments, a system comprises an integrated circuit (IC) die comprising a multi-transistor structure, comprising a plurality of vertically aligned semiconductor structures, an independent gate electrode surrounding a channel region of each of the semiconductor structures, the independent gate electrodes vertically aligned and separated by isolation layers, each isolation layer on neighboring ones of the gate electrodes, and an independent source or drain coupled to each of the channel regions of the semiconductor structures, the independent gate sources or drains vertically aligned and separated by second isolation layers, each second isolation layer on neighboring ones of the sources or drain, and a power supply coupled to the IC die.

In one or more fifteenth embodiments, further to the fourteenth embodiments, a first of the semiconductor structures comprises a p-type semiconductor material and a second of the semiconductor structures comprises an n-type semiconductor material.

In one or more sixteenth embodiments, further to the fourteenth or fifteenth embodiments, a first independent gate electrode coupled to the first semiconductor structure comprises a first metal composition and a second independent gate electrode coupled to the second semiconductor structure comprises a second metal composition.

In one or more seventeenth embodiments, further to the fourteenth through sixteenth embodiments, the system further comprises a conductor between a first and second of the semiconductor structures, the conductor separated from the gate electrodes by isolation material, and the conductor coupled to one or more of a plurality of second vertically aligned semiconductor structures.

In one or more eighteenth embodiments, a method comprises forming a plurality of vertically aligned semiconductor structures, forming a gate dielectric layer on and surrounding a channel region of each of the semiconductor structures, forming a first gate electrode on the gate dielectric layer of a first of the semiconductor structures, depositing an isolation layer on the first gate electrode and the gate dielectric layer of a second of the semiconductor structures, exposing the gate dielectric layer of the second of the semiconductor structures, and depositing a second gate electrode on the isolation layer on the gate electrode and on the exposed gate dielectric layer of the second of the semiconductor structures.

In one or more nineteenth embodiments, further to the eighteenth embodiments, the first semiconductor structure comprises a semiconductor material of a first type and the second semiconductor structure comprises a semiconductor material of a second type.

In one or more twentieth embodiments, further to the eighteenth or nineteenth embodiments, the method further comprises depositing, a sacrificial material on the isolation layer on the first gate electrode, depositing a second isolation layer on the sacrificial material, removing the sacrificial material, and forming a conductor between the second isolation layer and the isolation layer on the first gate electrode.

In one or more twenty-first embodiments, further to the eighteenth through twentieth embodiments, forming the first gate electrode on the gate dielectric layer of a first of the semiconductor structures comprises providing a bulk gate electrode material and recess etching the bulk gate electrode material to form the gate electrode having a top surface between the first and second semiconductor structures.

In one or more twenty-second embodiments, further to the eighteenth through twenty-first embodiments, the method further comprises removing a portion of each of the semiconductor structures to expose ends of the semiconductor structures, growing a first source or drain on the end of a first of the semiconductor structures, depositing a second isolation layer on the first source or drain, and growing a second source or drain on the end of a second of the semiconductor structures second isolation layer, the second isolation layer between the first and second sources or drains.

In one or more twenty-third embodiments, further to the eighteenth through twenty-second embodiments, the method further comprises recess etching, prior to said depositing the second isolation layer, a portion of a first source or drain bulk material to form the first source or drain.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A device, comprising:
a plurality of vertically aligned semiconductor structures;
a gate dielectric layer on and surrounding a channel region of each of the semiconductor structures; and
an independent gate electrode on each of the gate dielectric layers and surrounding each of the channel regions, the independent gate electrodes vertically aligned and separated by isolation layers, each isolation layer on neighboring ones of the gate electrodes.

2. The device of claim 1, further comprising:
an independent source or drain coupled to each of the channel regions of the semiconductor structures, the independent gate sources or drains vertically aligned and separated by second isolation layers, each second isolation layer on neighboring ones of the sources or drains.

3. The device of claim 1, wherein a first of the semiconductor structures comprises a p-type semiconductor material and a second of the semiconductor structures comprises an n-type semiconductor material.

4. The device of claim 3, wherein a first independent gate electrode coupled to the first semiconductor structure comprises a first metal composition and a second independent gate electrode coupled to the second semiconductor structure comprises a second metal composition.

5. The device of claim 4, wherein a third of the semiconductor structures adjacent to the first semiconductor structure comprises the p-type semiconductor material or a second p-type semiconductor material, and a fourth of the semiconductor structures adjacent to the second semiconductor structure comprises the n-type semiconductor material or a second n-type semiconductor material.

6. The device of claim 5, wherein a third independent gate electrode is coupled to the third semiconductor structure, and a fourth independent gate electrode is coupled to the fourth semiconductor structure, and wherein the first and third gate electrodes are separated by a first isolation layer having a first composition and the second and fourth gate electrodes are separated by a second isolation layer having a second composition.

7. The device of claim 3, further comprising:
a first source or drain comprising a first material coupled to the first semiconductor structure; and
a second source or drain comprising a second material coupled to the second semiconductor structure.

8. The device of claim 1, further comprising:
a conductor between a first and second of the semiconductor structures, the conductor separated from the gate electrodes by isolation material, and the conductor coupled to one or more of a plurality of second vertically aligned semiconductor structures.

9. The device of claim 8, wherein the conductor extends between first and second independent sources or drains coupled to channel regions of the first and second semiconductor structures.

10. The device of claim 1, wherein the semiconductor structures comprise a plurality of nanoribbons, a plurality of nanosheets, or a plurality of fins.

11. The device of claim 1, wherein a first of the semiconductor structures has a thickness in the vertical direction of not more than 2 nm.

12. The device of claim 11, further comprising:
a cooling structure operable to remove heat from an IC die comprising the semiconductor structures to achieve an operating temperature at or below −25° C.

13. A system, comprising:
an integrated circuit (IC) die comprising a multi-transistor structure, comprising:
a plurality of vertically aligned semiconductor structures;
an independent gate electrode surrounding a channel region of each of the semiconductor structures, the independent gate electrodes vertically aligned and separated by isolation layers, each isolation layer on neighboring ones of the gate electrodes; and
an independent source or drain coupled to each of the channel regions of the semiconductor structures, the independent gate sources or drains vertically aligned and separated by second isolation layers, each second isolation layer on neighboring ones of the sources or drains; and
a power supply coupled to the IC die.

14. The system of claim 13, wherein a first of the semiconductor structures comprises a p-type semiconductor material and a second of the semiconductor structures comprises an n-type semiconductor material.

15. The system of claim 14, wherein a first independent gate electrode coupled to the first semiconductor structure comprises a first metal composition and a second independent gate electrode coupled to the second semiconductor structure comprises a second metal composition.

16. The system of claim 13, further comprising:
a conductor between a first and second of the semiconductor structures, the conductor separated from the gate electrodes by isolation material, and the conductor coupled to one or more of a plurality of second vertically aligned semiconductor structures.

17. A method, comprising:
forming a plurality of vertically aligned semiconductor structures;
forming a gate dielectric layer on and surrounding a channel region of each of the semiconductor structures;
forming a first gate electrode on the gate dielectric layer of a first of the semiconductor structures;
depositing an isolation layer on the first gate electrode and the gate dielectric layer of a second of the semiconductor structures;
exposing the gate dielectric layer of the second of the semiconductor structures; and
depositing a second gate electrode on the isolation layer on the gate electrode and on the exposed gate dielectric layer of the second of the semiconductor structures.

18. The method of claim 17, wherein the first semiconductor structure comprises a semiconductor material of a first type and the second semiconductor structure comprises a semiconductor material of a second type.

19. The method of claim 18, further comprising:
depositing, a sacrificial material on the isolation layer on the first gate electrode;
depositing a second isolation layer on the sacrificial material;
removing the sacrificial material; and
forming a conductor between the second isolation layer and the isolation layer on the first gate electrode.

20. The method of claim 17, wherein forming the first gate electrode on the gate dielectric layer of a first of the semiconductor structures comprises providing a bulk gate electrode material and recess etching the bulk gate electrode material to form the gate electrode having a top surface between the first and second semiconductor structures.

21. The method of claim 17, further comprising:
removing a portion of each of the semiconductor structures to expose ends of the semiconductor structures;
growing a first source or drain on the end of a first of the semiconductor structures;
depositing a second isolation layer on the first source or drain; and
growing a second source or drain on the end of a second of the semiconductor structures second isolation layer, the second isolation layer between the first and second sources or drains.

22. The method of claim 21, further comprising:
recess etching, prior to said depositing the second isolation layer, a portion of a first source or drain bulk material to form the first source or drain.
